(19) United States
(12) Patent Application Publication
(10) Pub. No.: US 2020/0413557 A1
(43) Pub. Date: Dec. 31, 2020

(54) BENDABLE ASSEMBLY AND FLEXIBLE DISPLAY DEVICE

(71) Applicant: SHENZHEN ROYOLE TECHNOLOGIES CO., LTD., Shenzhen (CN)

(72) Inventor: Qiang ZHANG, Shenzhen (CN)

(21) Appl. No.: 17/017,566

(22) Filed: Sep. 10, 2020

Related U.S. Application Data
(63) Continuation of application No. PCT/CN2018/078690, filed on Mar. 12, 2018.

(51) Int. Cl. H05K 5/02; E05D 11/00; E05D 3/18; E05D 3/12

(52) U.S. Cl. CPC H05K 5/0226; E05D 11/00; E05Y 2900/606; E05D 3/122; E05D 3/18

(57) ABSTRACT

A bendable assembly and a flexible display device are provided. The bendable assembly includes a hinge module, a resilient member, and a casing plate. The resilient member is connected with the casing plate and the hinge module. The hinge module is configured for being switched between a bent state and an unfolded state. The hinge module and the casing plate move toward each other during the bendable assembly switches from the unfolded state to the bent state. The hinge module and the casing plate move relatively away from each other during the bendable assembly switches from the bent state to the unfolded state. The resilient member is configured to drive the casing plate and the hinge module to move relatively away from each other during the hinge module switches from the bent state to the unfolded state.

### CROSS-REFERENCE TO RELATED APPLICATIONS

The present application is a continuation of International Application No. PCT/CN2018/078690, filed on Mar. 12, 2018, the disclosure of which is hereby incorporated by reference in its entirety.

### TECHNICAL FIELD

This disclosure relates to the technical field of flexible display, and particularly to a bendable assembly and a flexible display device.

### BACKGROUND

Flexible screens are increasingly favored by consumers due to their flexibility. It needs to dispose the flexible screen on a bendable structure to achieve a bending of the flexible screen. An arc length of the flexible screen disposed on the bendable structure when the bendable structure is in a bent state is larger than a linear length of the flexible screen when the bendable structure is in an unfolded state, and thus the flexible screen is stretched during bending the flexible screen, and thus the flexible screen is easily damaged and the service life of the flexible screen is affected.

### SUMMARY

According to the present disclosure, a bendable assembly and a flexible display device are provided.

The bendable assembly is provided according to the present disclosure. The bendable assembly includes a hinge module, a resilient member, and a casing plate. The resilient member is connected with the casing plate and the hinge module. The hinge module is configured for being switched between a bent state and an unfolded state. The hinge module and the casing plate move toward each other during the bendable assembly switches from the unfolded state to the bent state. The hinge module and the casing plate move relatively away from each other during the bendable assembly switches from the bent state to the unfolded state. The resilient member is configured to drive the casing plate and the hinge module to move relatively away from each other during the hinge module switches from the bent state to the unfolded state.

A flexible display device according to embodiments of the present disclosure includes the bendable assembly of the above mentioned embodiment and a flexible screen assembly fixedly disposed on the bendable assembly.

For the bendable assembly and the flexible display device in the embodiments of the present disclosure, when the bendable assembly is bent, the hinge module and the casing plate moving relatively close to each other compensates for a change in an arc length of a bendable portion of the hinge module during bending the hinge module, thereby preventing a flexible screen mounted on the bendable assembly from being stretched and damaged and ensuring the service life of the flexible screen. Also, the flexible screen can be flattened when the hinge module is in the unfolded state.

Additional aspects and advantages of the present disclosure will be partly presented in the following description, partly become apparent in the following description or be appreciated in practicing of the present disclosure.

### BRIEF DESCRIPTION OF THE DRAWINGS

Above and/or additional aspects and advantages of the present disclosure will be apparent and readily appreciated from the following description of embodiments with reference to the accompanying drawings, in which:

FIG. 1 is an exploded schematic view of a flexible display device according to an embodiment of the present disclosure.

FIG. 2 is a partially exploded schematic view of the flexible display device according to an embodiment of the present disclosure.

FIG. 3 is another partially exploded schematic view of the flexible display device according to an embodiment of the present disclosure.

FIG. 4 is a schematic plan view of a bendable assembly according to an embodiment of the present disclosure.

FIG. 5 is another schematic plan view of the bendable assembly according to an embodiment of the present disclosure.

FIG. 6 is a schematic view of a hinge module in an unfolded state according to an embodiment of the present disclosure.

FIG. 7 is a schematic plan view of the hinge module in the unfolded state according to an embodiment of the present disclosure.

FIG. 8 is another schematic plan view of the hinge module in the unfolded state according to an embodiment of the present disclosure.

FIG. 9 is yet another schematic plan view of the hinge module in the unfolded state according to an embodiment of the present disclosure.

FIG. 10 is a schematic plan view of the hinge module in a bent state according to an embodiment of the present disclosure.

FIG. 11 is another schematic plan view of the hinge module in the bent state according to an embodiment of the present disclosure.

FIG. 12 is a partially exploded view of the bendable assembly according to an embodiment of the present disclosure.

FIG. 13 is another partially exploded view of the bendable assembly according to an embodiment of the present disclosure.

FIG. 14 is a schematic view of a first connecting hinge and a second rotating shaft according to an embodiment of the present disclosure.

FIG. 15 is a schematic view of a first gear set according to an embodiment of the present disclosure.

FIG. 16 is a schematic plan view of the bendable assembly in the unfolded state according to another embodiment of the present disclosure.

FIG. 17 is a schematic plan view of the bendable assembly in the bent state according to another embodiment of the present disclosure.

FIG. 18 is another schematic plan view of the bendable assembly in the bent state according to another embodiment of the present disclosure.

FIG. 19 is a schematic view of the hinge module in the unfolded state according to another embodiment of the present disclosure.

FIG. 20 is a schematic plan view of the hinge module in the unfolded state according to another embodiment of the present disclosure.

FIG. 21 is a schematic view of a casing plate according to an embodiment of the present disclosure.

### REFERENCE NUMBERS INDICATING MAIN MEMBERS ARE DESCRIBED AS FOLLOWS

bendable assembly 10, hinge module 12, second side portion 121, second guiding structure 1212, first connecting hinge 122, second connecting hinge 124, rotatable shaft structure 126, first rotating shaft 1262, second rotating shaft 1264, third rotating shaft 1266, synchronous gear module 128, first gear set 1282, second gear set 1284, third gear set 1286, first gear 128a, second gear 128b, holder 128c, positioning rod 128d, third gear 128e, connecting member 13, first slide rail 132, second slide rail 134, casing plate 14, first plate 142, first sliding seat 1422, second plate 144, second sliding seat 1442, positioning seat 146, first side portion 148, first guiding structure 1482, groove 15, second through hole 152, resilient member 16, accommodating groove 17, positioning post 18, flexible screen assembly 20, flexible support plate 22, protrusion 222, first through hole 224, flexible screen 24, fastener 26, flexible rubber ring 30, flexible display device 100.

### DETAILED DESCRIPTION OF ILLUSTRATED EMBODIMENTS

Embodiments of the present disclosure will be described in detail as following and examples of the embodiments will be illustrated in the accompanying drawings, where same or similar reference numerals are used to indicate same or similar members or members with same or similar functions. The embodiments described herein with reference to the accompanying drawings are exemplary, and are intended to describe the present disclosure and cannot be construed as a limitation to the present disclosure.

In the description of the present disclosure, it is to be understood that, orientations or position relationships indicated by terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise” are orientations or position relationships shown based on the accompanying drawings, and are merely used for describing the present disclosure and simplifying the description, rather than indicating or implying that the apparatus or element should have a particular orientation or be constructed and operated in a particular orientation, and therefore, should not be construed as a limitation to the present disclosure.

In addition, terms “first” and “second” are used only for description purposes, and shall not be understood as indicating or suggesting relative importance or implicitly indicating a quantity of indicated technical features. Therefore, features defined by “first” and “second” may explicitly or implicitly include one or more of the above-mentioned features. In the description of the present disclosure, unless otherwise specifically limited, “multiple”, “a plurality of”, and “a number of” mean there are at least two elements.

In the embodiments of the present disclosure, it is appreciated that terms “dispose”, “interconnect”, and “connect” should be understood in a broad sense unless otherwise specified and limited. For example, terms “interconnect” and “connect” may refer to fixedly connect, detachably connect, or integrally connect. The terms “interconnect” and “connect” may also refer to mechanically connect, electrically connect, or communicate with each other. The terms “interconnect” and “connect” may also refer to directly connect, indirectly connect through an intermediate medium, intercommunicate interiors of two elements, or interact between two elements. For those of ordinary skill in the art, the specific meanings of the above terms in the embodiments of the present disclosure can be understood according to specific situations.

In the embodiments of the present disclosure, unless otherwise specified and limited, a first feature being disposed “above” or “below” a second feature may indicate that the first feature and the second feature are directly contacted with each other, or the first feature and the second feature are indirectly contacted via an intermediate medium. Moreover, the first feature being disposed “above” the second feature may indicate that the first feature is directly above or obliquely above the second feature, or merely indicate that the first feature is higher in horizontal height than the second feature. The first feature being disposed “below” the second feature may indicate that the first feature is directly below or obliquely below the second feature, or merely indicate that the first feature is lower in the horizontal height than the second feature.

Various embodiments or examples are provided herein for realizing various structures. To simplify the disclosure of the present disclosure, components and arrangements of specific examples are described below, and of course, are only exemplary and are not intended to limit the present disclosure. In addition, same reference numerals and/or reference letters can be repeated in different embodiments according to the present disclosure, and such repetition is for the purpose of simplification and clarity, without indicating the relationships between various embodiments and/or arrangements in discuss. Moreover, the present disclosure provides examples of various specific processes and materials, but the applicability of other processes and/or disclosure of other materials may be appreciated by those having ordinary skill in the art.

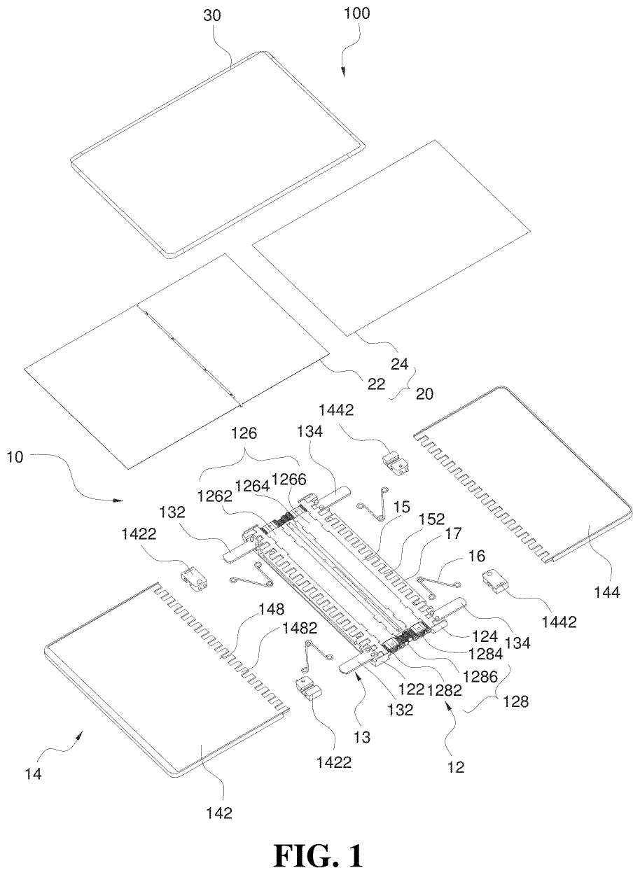

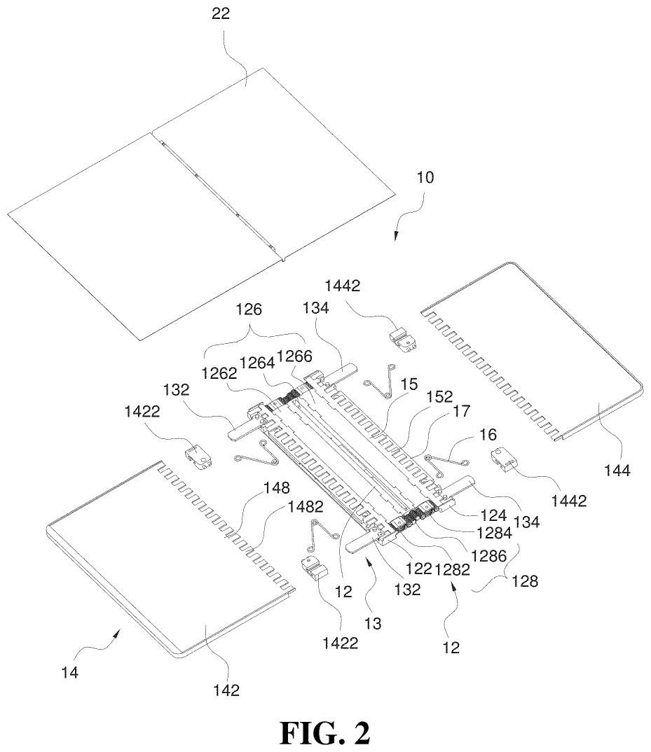

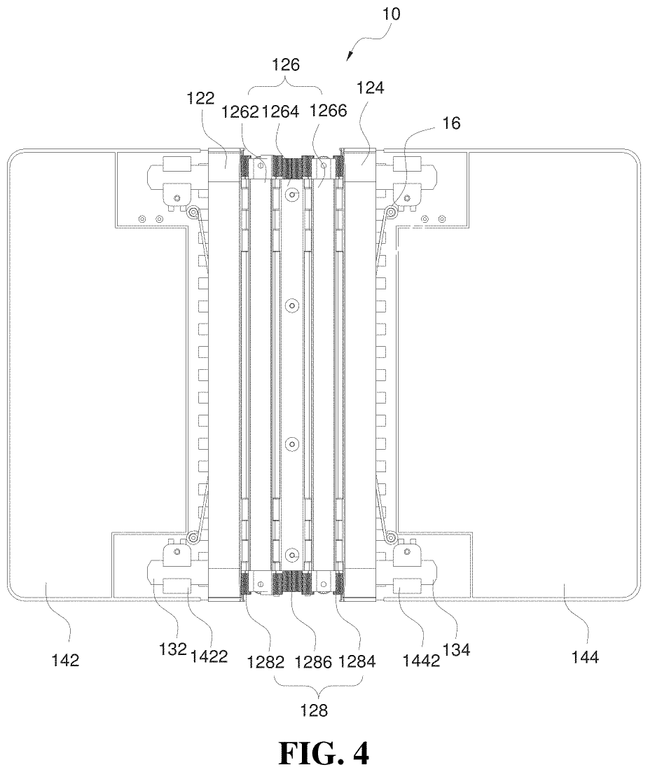

Referring to FIGS. 1-5, a bendable assembly 10 is provided according to the embodiments of the present disclosure. The bendable assembly 10 includes a hinge module 12, a resilient member 16, and a casing plate 14. The resilient member 16 is connected with the casing plate 14 and the hinge module 12. The hinge module 12 is configured for being switched between a bent state and an unfolded state. The hinge module 12 and the casing plate 14 move toward each other during the bendable assembly 10 switches from the unfolded state to the bent state. The hinge module 12 and the casing plate 14 move relatively away from each other during the bendable assembly 10 switches from the bent state to the unfolded state. The resilient member 16 is configured to drive the casing plate 14 and the hinge module 12 to move relatively away from each other during the hinge module 12 switches from the bent state to the unfolded state.

During the bendable assembly 10 switches between the bent state and the unfolded state, the resilient member 16 stretches out and draws back to generate a driving force, thus a relative displacement between the hinge module 12 and the casing plate 14 is driven to change by the driving force, thereby preventing a flexible screen 24 mounted on the bendable assembly 10 from being stretched and damaged and ensuring the service life of the flexible screen 24. Also, the flexible screen 24 can be flattened when the hinge module 12 is in the unfolded state.

In an embodiment, the resilient member 16 can provide a pushing force or a pulling force when a bending process of the bendable assembly 10 is not smooth, such that a warping of the flexible screen assembly 20 disposed on the bendable assembly 10 can be avoided. The resilient member 16 also provides a pushing force in the bending process and an unfolding process of the bendable assembly 10 to push the casing plate 14 to move, and thus the unfolding process is smooth to stabilize the casing plate 14, thereby avoiding warping of the flexible screen assembly 20.

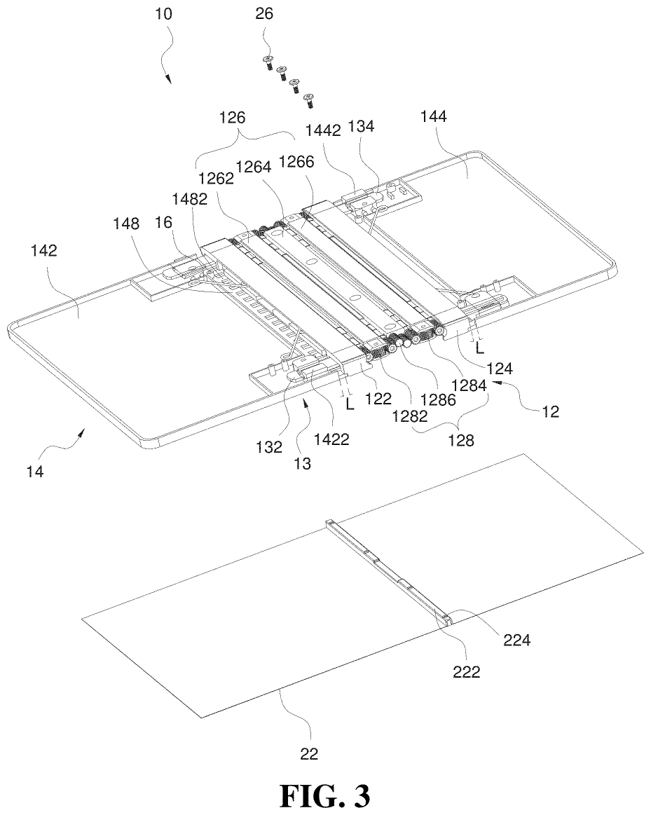

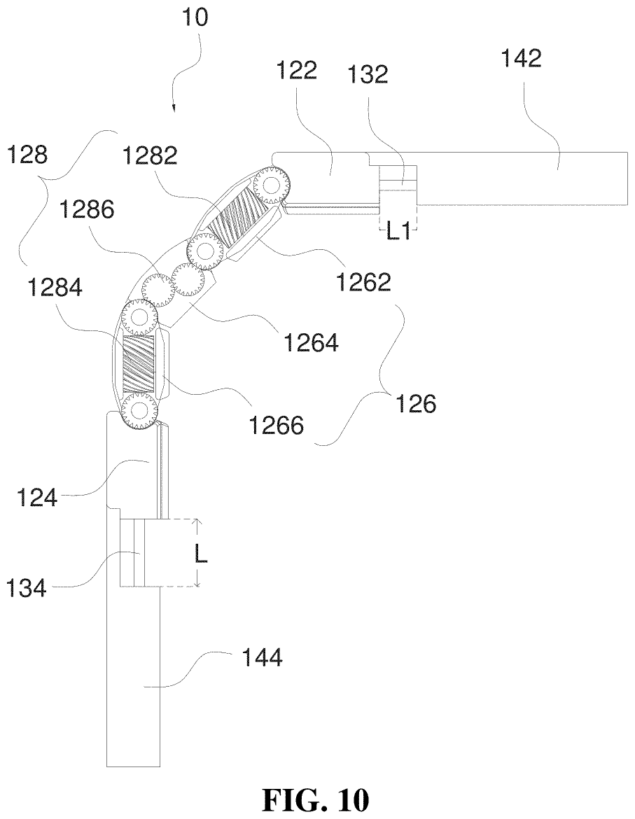

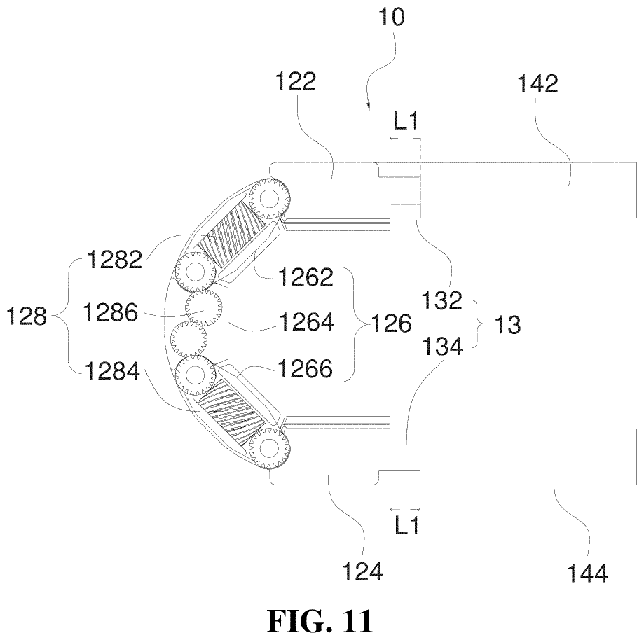

In an embodiment, referring to FIG. 3, when the hinge module 12 is in the unfolded state, a distance between the hinge module 12 and the casing plate 14 is expressed as L. Referring to FIG. 10 and FIG. 11, when the hinge module 12 is in the bent state, the hinge module 12 and the casing plate 14 move toward each other, such that the distance is decreased and expressed as Ll. A decrease of the distance L between the hinge module 12 and the casing plate 14 enables to provide an additional space for bending of the flexible screen 24, such that the flexible screen 24 is free of being stretched when the bendable assembly 10 is bent, thereby ensuring the service life of the flexible screen 24.

In embodiments illustrated in FIGS. 1 to 4, the resilient member 16 is in a V-shape, the resilient member 16 includes one distal end connected to the casing plate 14 and the other distal end connected to the hinge module 12.

In an embodiment, the resilient member 16 includes positioning portions formed at each end portion of the V-shape resilient member 16, and by passing screws, rivets or the like through the positioning portions or welding, the resilient member 16 can be fixed at a predetermined position. In an embodiment, the screws are selected, and thus a relative good fixing effect can be provided, disassembly is easy, implementation is relatively easy, operation is easy and flexible, and cost is low.

In an embodiment, one distal end of the resilient member 16 is rotatably or fixedly connected to the casing plate 14, and the other distal end of the resilient member 16 is rotatably or fixedly connected to the hinge module 12.

In an embodiment, when the two distal ends of the resilient member 16 are fixedly connected to the casing plate 14 and the hinge module 12 respectively, it is relatively easy to install the resilient member 16. When the two distal ends of the resilient member 16 are rotatably connected to the casing plate 14 and the hinge module 12 respectively, the resilient member 16 is subjected to a relatively small resistance during driving the casing plate 14 and the hinge module 12. Therefore, a connecting manner of the resilient member 16 connecting with the casing plate 14 and that of the resilient member 16 connecting with the hinge module 12 can be determined according to the actual situation. Of course, the connecting manner of the resilient member 16 and the casing plate 14 may be the same as or different from of the resilient member 16 and the hinge module 12.

More specifically, in this embodiment, two resilient members 16 are arranged to connect a first plate 142 and a first connecting hinge 122, and two resilient members 16 are arranged to connect a second plate 144 and a second connecting hinge 124. In this way, during the bendable assembly 10 is switched from the bent state to the unfolded state, the first plate 142 and the second plate 144 move relatively smoothly.

In an embodiment, the hinge module 12 defines accommodating grooves 17, and the resilient members are partially received in the accommodating grooves 17.

In an embodiment, the accommodating grooves 17 each are in an elongated shape. One of the accommodating grooves 17 is positioned at an outer side portion 121 of the first connecting hinge 122. Two first slide rails 132 are respectively arranged at two opposite ends of the accommodating groove 17, and each of the two first slide rails 132 is substantially perpendicular to the accommodating groove 17. The other of the accommodating grooves 17 is positioned at an outer side portion 121 of the second connecting hinge 124, two second slide rails 134 are respectively arranged at two opposite ends of the other accommodating groove 17, and each of the two second slide rails 134 is substantially perpendicular to the other accommodating groove 17. The resilient member 16 is partially accommodated in the accommodating groove 17, thus ensuring positional stability of the resilient member 16 and avoiding unexpected displacement during deformation of the resilient member 16, and furthermore, the casing plate 14 and the hinge module 12 can be driven to move relatively stable.

In an embodiment, the resilient member 16 is linear shape. The casing plate 14 provides a first positioning post (not illustrated). The hinge module 12 provides a second positioning post (not illustrated). The resilient member 16 is sleeved on the first positioning post and the second positioning post.

In this way, a positional relationship among the resilient member 16, the hinge module 12, and the casing plate 14 is stable, and a good pushing force and pulling force can be provided to ensure a relative movement between the hinge module 12 and the casing plate 14.

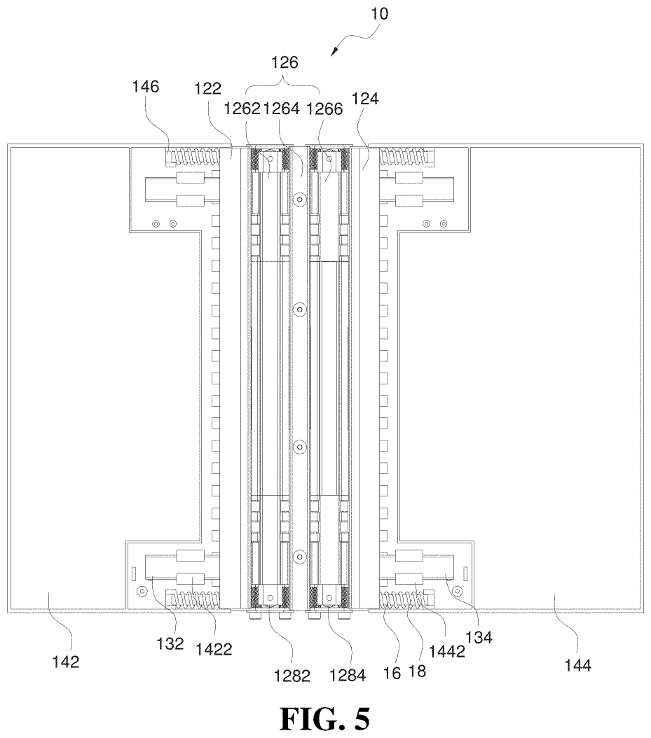

Referring to FIG. 5, in some embodiments, the resilient member 16 is linear shape. The hinge module 12 provides a positioning rod 18. The casing plate 14 provides with a positioning seat 146. One end of the positioning rod 18 can be embedded in the positioning seat 146. The resilient member 16 is sleeved on the positioning rod 18.

The resilient member 16 being linear shape means that the resilient member 16 is in a linear shape in natural state. In an embodiment, the resilient member 16 may be a cylindrical compression spring, that is, a coil spring that can bear axial pressure. A certain gap is defined between each two adjacent coils of the compression spring. When subjected to an external load, the resilient member 16 can contract and is deformed, and energy generated by a deformation of the resilient member 16 is stored to push the casing plate 14 and the hinge module 12 to move relative to each other. The positioning post 18 and the positioning seat 146 cooperate to fix the resilient member 16, such that the resilient member 16 is deformed in a preset direction to obtain a desired relative movement.

In one example, the resilient member 16 may be made of spring steel.

Spring steel is a special alloy steel for manufacturing various springs and other resilient members 16. Spring steel has the following comprehensive properties, such as mechanical properties, elasticity attenuation resistance, fatigue properties, hardenability, physical and chemical properties. Spring steel has excellent metallurgical quality, good surface quality, and precise shape and size, etc.

In one example, the resilient member 16 can be made by a cold forming process or a hot forming process.

The cold forming process and the hot forming process are mature processes and can be used to produce and manufacture the resilient member 16 with relatively good quality and relatively long service life.

In an embodiment of the present disclosure, the bendable assembly 10 includes a connecting member 13 in a sheet shape. The connecting member 13 is slidably connected with the casing plate 14 and the hinge module 12. The connecting member 13 guides the hinge module 12 and the casing plate 14 to move toward each other during the bendable assembly 10 switches from the unfolded state to the bent state. The connecting member 13 guides the hinge module 12 and the casing plate 14 to move relatively away from each other during the bendable assembly 10 switches from the bent state to the unfolded state.

During bending the bendable assembly 10, the connecting member 13 guides relative movement between the hinge module 12 and the casing plate 14, so as to compensate for the change in the arc length of the bendable portion of the hinge module 10 during bending the hinge module 10, thereby preventing a flexible screen 24 mounted on the bendable assembly 10 from being stretched and damaged and ensuring the service life of the flexible screen 24. Further, the flexible screen 24 can be flattened when the hinge module 12 is in the unfolded state.

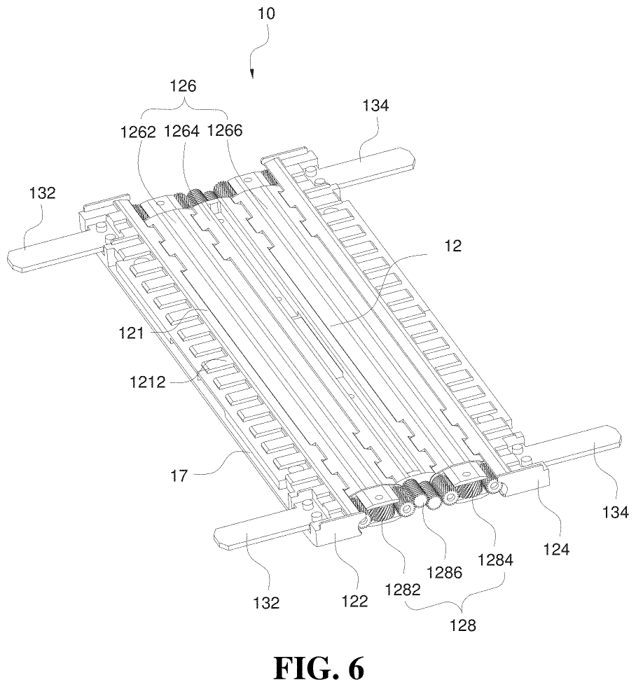

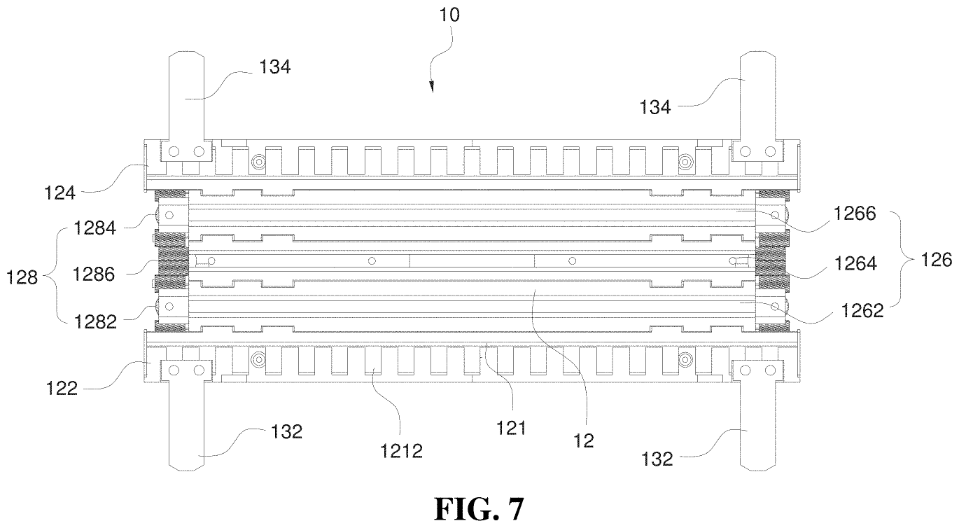

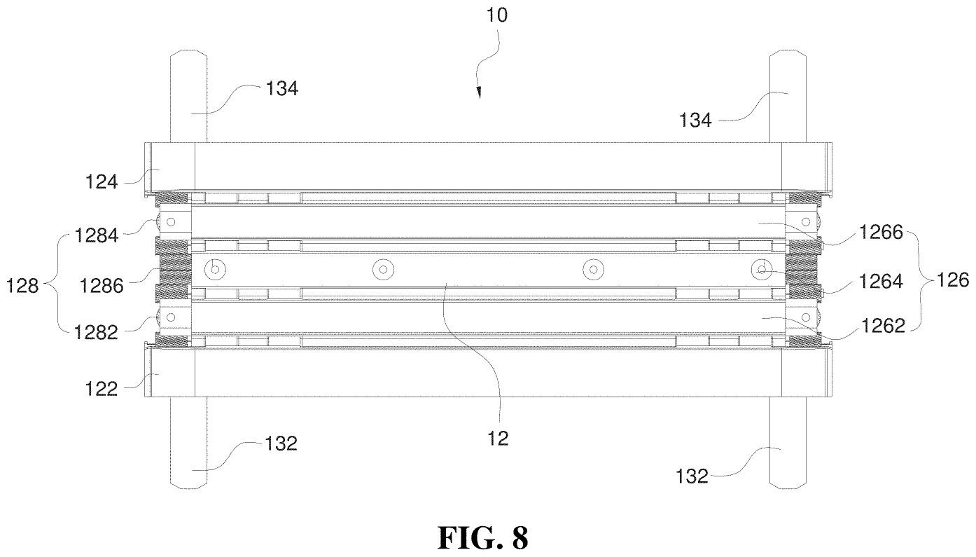

Referring to FIGS. 6-8 and FIG. 21, in an embodiment of the present disclosure, the hinge module 12 includes a first connecting hinge 122, a second connecting hinge 124, and a rotatable shaft structure 126. The casing plate 14 includes a first plate 142 and a second plate 144. The first connecting hinge 122 and the second connecting hinge 124 are respectively rotatably connected to two opposite sides of the rotatable shaft structure 126. The connecting member 13 includes a first slide rail 132 and a second slide rail 134. The first slide rail 132 is fixedly connected to the first connecting hinge 122 and slidably connected to the first plate 142. The second slide rail 132 is fixedly connected to the second connecting hinge 124 and slidably connected to the second plate 144.

In an embodiment, a portion of the first connecting hinge 122 is rotatably connected with and fitted with a portion of the rotatable shaft structure 126 via shaft elements, and a portion of the second connecting hinge 124 is rotatably connected with and fitted with the other portion of the rotatable shaft structure 126 via shaft elements, thereby improving space utilization on premise of ensuring stability of rotational connections. In this way, the hinge module 12 has a simple positional relationship, which is convenient for assembling the bendable assembly 10 with a simple structural relationship, and thus it is easy to form a flexible display device 100, thereby reducing production cost and manufacturing difficulty.

In an embodiment of the present disclosure, the first slide rail 132 is in a plate shape. An end of the first slide rail 132 away from the first connecting hinge 122 is in an arc shape. In this way, with the first slide rail 132 having the end in an arc shape, it is easy to assemble the first slide rail 132 and the first plate 142. A structure of the second slide rail 134 is similar to that of the first slide rail 132 and will not be repeated in detail herein.

The first slide rail 132 is substantially perpendicular to the first connecting hinge 122, and the second slide rail 134 is substantially perpendicular to the second connecting hinge 124. The first slide rail 132 and the second slide rail 134 can be fixedly connected to the first connecting hinge 122 and the second connecting hinge 124 by screw fixing, rivet fixing, or welding.

The first slide rail 132 and the second slide rail 134 are substantially perpendicular to the first connecting hinge 122 and the second connecting hinge 124, respectively, such that the first slide rail 132 and the second slide rail 134 can orderly slide in the first plate 142 and the second plate 144. The screw fixing, the rivet fixing, and the welding are simple, mature in process, and low in price, such that production cost and difficulty can be reduced, and economic benefit can be improved.

In other embodiments, the first slide rail 132 can be fixedly connected to the first plate 142 and slidably connected to the first connecting hinge 122. The second slide rail 134 can be fixedly connected to the second plate 144 and slidably connected to the second connecting hinge 124.

In an embodiment of the present disclosure, the first plate 142 provides with a first sliding seat 1422, and the first slide rail 132 slidably passes through the first sliding seat 1422. In this way, it is easy to assemble the first slide rail 132 and the first plate 142, and thus the production efficiency of the bendable assembly 10 can be improved.

In an embodiment, the first sliding seat 1422 can be fixed on the first plate 142 by screwing, gluing, or welding, or be integrally formed with the first plate 142. The first sliding seat 1422 defines a first sliding groove, and the first slide rail 132 passes through the first sliding groove and is slidably connected with the first sliding seat 1422.

In embodiments illustrated in the drawings, the first sliding seat 1422 is in a substantially cuboid shape. Of course, a shape of the first sliding seat 1422 is not limited to be a cuboid, and may be a regular or irregular polygon with a sliding space for the first slide rail 132 to slide, such as a square, a circle, a trapezoid, etc., which can be specifically determined in a specific embodiment.

In other embodiments of the present disclosure, under the condition that the first slide rail 132 is slidably connected with the first connecting hinge 122, the first connecting hinge 122 provides with the first sliding seat 1422, and the first slide rail 132 slidably passes through the first sliding seat 1422.

In an embodiment of the present disclosure, the second plate 144 provides with a second sliding seat 1442, and the second slide rail 134 slidably passes through the second sliding seat 1442. In this way, it is easy to assemble the second slide rail 134 and the second plate 144, and thus the production efficiency of the bendable assembly 10 can be increased.

In an embodiment, the second sliding seat 1442 can be fixed on the second plate 144 by screwing, gluing, or welding, or be integrally formed with the second plate 144. The second sliding seat 1442 defines a second sliding groove, and the second slide rail 134 passes through the second sliding groove and is slidably connected with the second sliding seat 1442.

In the embodiments illustrated in the drawings, the second sliding seat 1442 is in a substantially cuboid shape. Of course, a shape of the second sliding seat 1442 is not limited to be a cuboid, and may be a regular or irregular polygon with a sliding space for the second slide rail 134 to slide, such as a square, a circle, a trapezoid, etc., which can be specifically determined in the specific embodiment.

In other embodiments, under the condition that the second slide rail 134 is slidably connected with the second connecting hinge 124, the second connecting hinge 124 provides with the second sliding seat 1442, and the second slide rail 134 slidably passes through the second sliding seat 1442.

There are two first slide rails 132, two second slide rails 134, two first sliding seats 1422, and two second sliding seats 1442, and they are disposed at preset positions. For example, in the embodiments illustrated in the drawings, a planar shape of the bendable assembly 10 is substantially rectangular. The first slide rail 132, the second slide rail 134, the first sliding seat 1422, and the second sliding seat 1442 each can be respectively arranged at a position close to a long side edge of the bendable assembly 10, and an advantage is that space close to a middle of the bending assembly 10 can be reserved to arrange other elements or structures.

Of course, the number of the first slide rails 132, the number of the second slide rails 134, the number of the first sliding seats 1422, and the number of the second sliding seats 1442 each are not limited to two, and may be one, three, four, or the like, and may be set to be a specific value under the premise of ensuring quality and a smooth bending process of the bendable assembly 10. In the embodiments of the present disclosure, there are two first slide rails 132, two second slide rails 134, two first sliding seats 1422, and two second sliding seats 1442, so as to achieve stable sliding and connection.

In an embodiment of the present disclosure, the first connecting hinge 122, the rotatable shaft structure 126, and the second connecting hinge 124 rotate synchronously.

In this way, a smooth and gentle bending process of the bendable assembly 10 can be ensured, such that an unfolding and bending process of the flexible display device 100 is smooth, and consumer experience is improved.

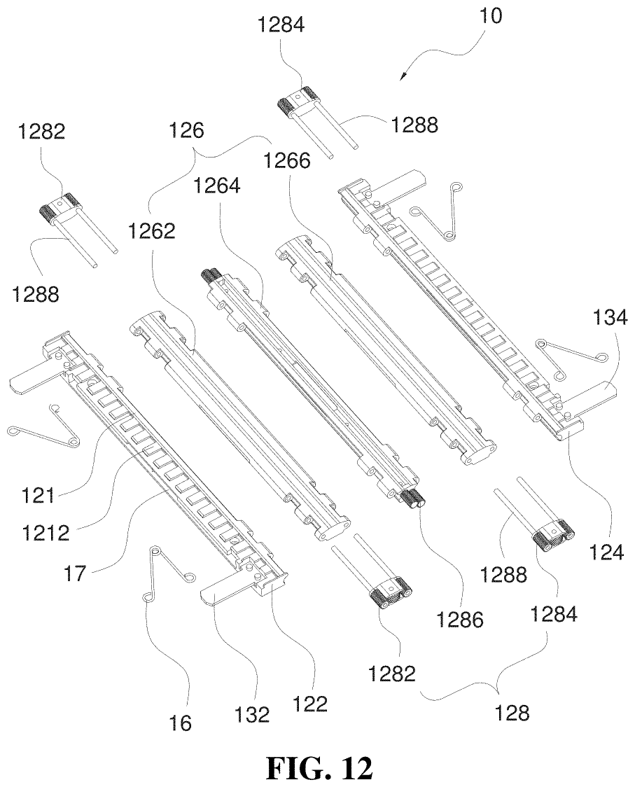

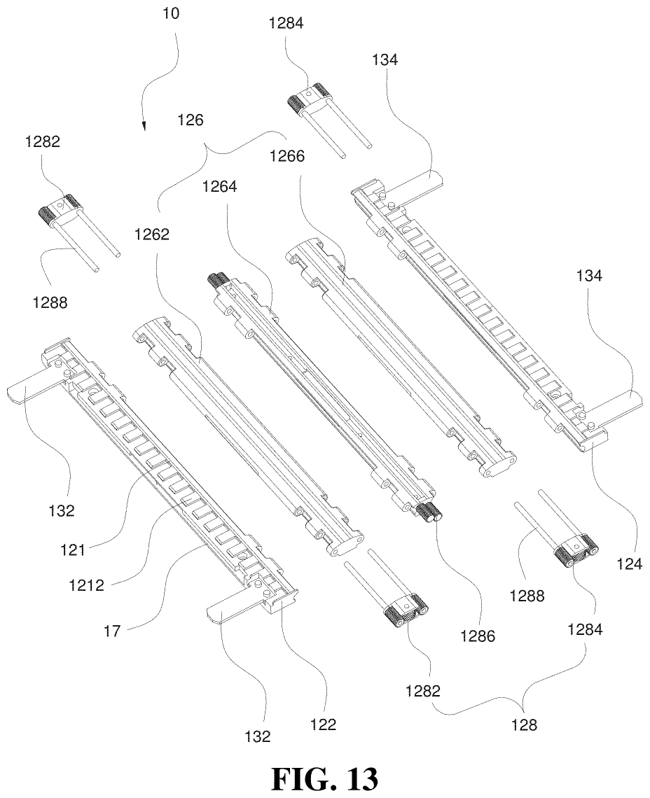

In an embodiment, referring to FIG. 12 and FIG. 13, the hinge module 12 includes a synchronous gear module 128. The synchronous gear module 128 includes a first gear set 1282 and a second gear set 1284. The first gear set 1282 is rotatably connected with the first connecting hinge 122 and the rotatable shaft structure 126. The second gear set 1284 is rotatably connected with the second connecting hinge 124 and the rotatable shaft structure 126. In this way, a synchronous rotation of the first connecting hinge 122, the rotatable shaft structure 126, and the second connecting hinge 124 is realized through a gear structure, and it is simple and reliable in structure and low in cost.

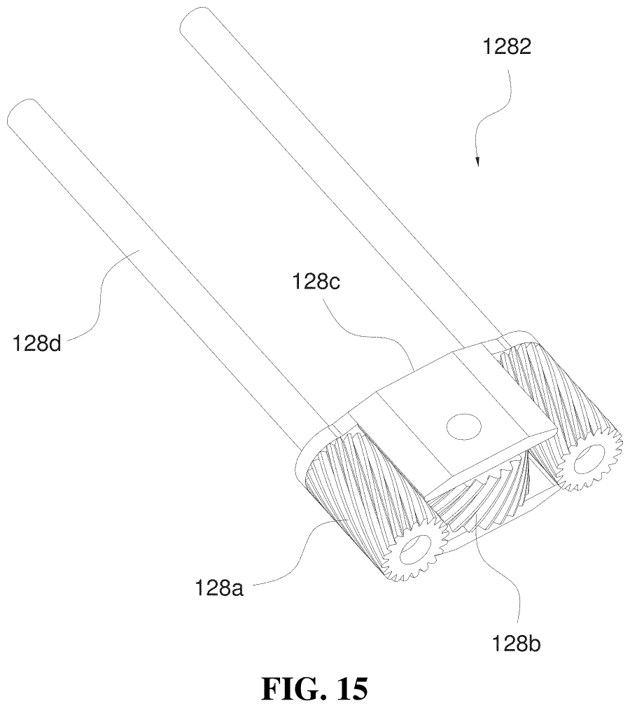

Further referring to FIG. 15, the first gear set 1282 includes two first gears 128a, a second gear 128b, a holder 128c, and a positioning rod 128d. The two first gear 128a and the second gear 128b each are in a substantially cylindrical shape. The two first gear 128a are spaced apart from each other and mesh with the second gear 128b. An axis about which each of the two first gears 128a rotates is perpendicular to a bottom surface of the holder 128c. An axis about which the second gear 128b rotates is perpendicular to the bottom surface of the holder 128c. The axis about which each of the two first gears 128a rotates is perpendicular to the axis about which the second gear 128b rotates. The positioning rod 128d is perpendicularly fixed to an inner side surface of the holder 128c. The positioning rod 128d passes through and links the first connecting hinge 122 and the rotatable shaft structure 126. The first gear 128a and the second gear 128b both are helical gears.

In addition, there are two first gear sets 1282, which are disposed at two opposite ends of the rotatable shaft structure 126 respectively. In this way, the synchronous rotation of the first gear set 1282 and the rotatable shaft structure 126 is relatively stable.

A structure and position of the second gear set 1284 are similar to that of the first gear set 1282 and will not be repeated in detail herein.

In an embodiment, the rotatable shaft structure 126 includes a first rotating shaft 1262, a second rotating shaft 1264, and a third rotating shaft 1266. The first rotating shaft 1262 and the third rotating shaft 1266 are respectively rotatably connected to two opposite sides of the second rotating shaft 1264. The first gear set 1282 is disposed at one end of the first rotating shaft 1262, the second gear set 1284 is disposed at one end of the third rotating shaft 1266. In this way, the three rotating shafts can meet most of bending angle requirements of the bendable assembly 10.

In an embodiment, the two first gear sets 1282 are respectively disposed at the two opposite ends of the first rotating shaft 1262, and two second gear sets 1284 are respectively disposed at the two opposite ends of the third rotating shaft 1266.

Of course, a specific embodiment of the rotatable shaft structure 126 is not limited to the embodiment discussed above and can be determined according to requirements. For example, in some embodiments, more rotating shafts can be used. For example, a multi-rotating shaft structure with two rotating shafts, four rotating shafts, or five rotating shafts can be used to form the rotating shaft structure 126, so as to provide various bending angles and a relatively smooth bending of the bendable assembly 10. It can be understood that fewer rotating shafts enable the rotatable shaft structure 126 to be simple in structure and low in cost. More rotating shafts enable the bending angle of the rotatable shaft structure 126 to be more diversified.

In one example, the hinge module 12 can be made of martensitic stainless steel. That is, the first connecting hinge 122, the second connecting hinge 124, the first rotating shaft 1262, the second rotating shaft 1264, and the third rotating shaft 1266 may all be made of martensitic stainless steel.

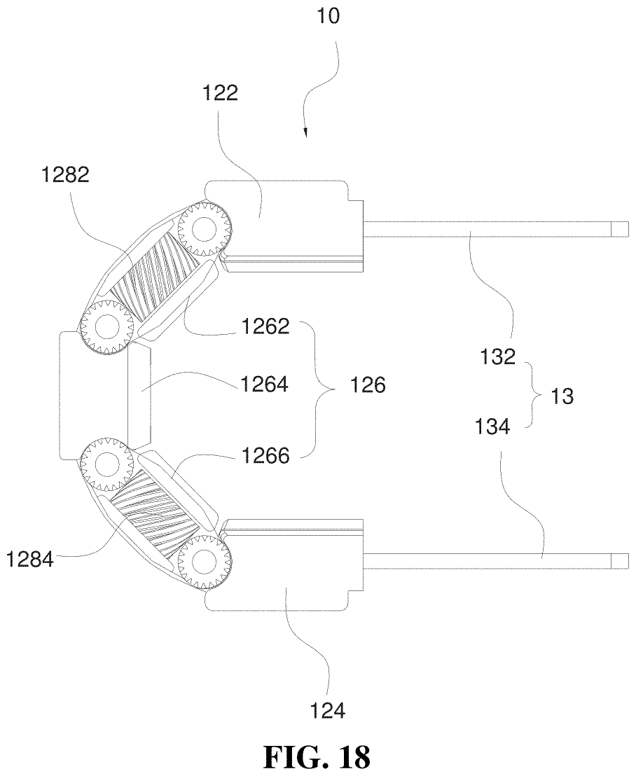

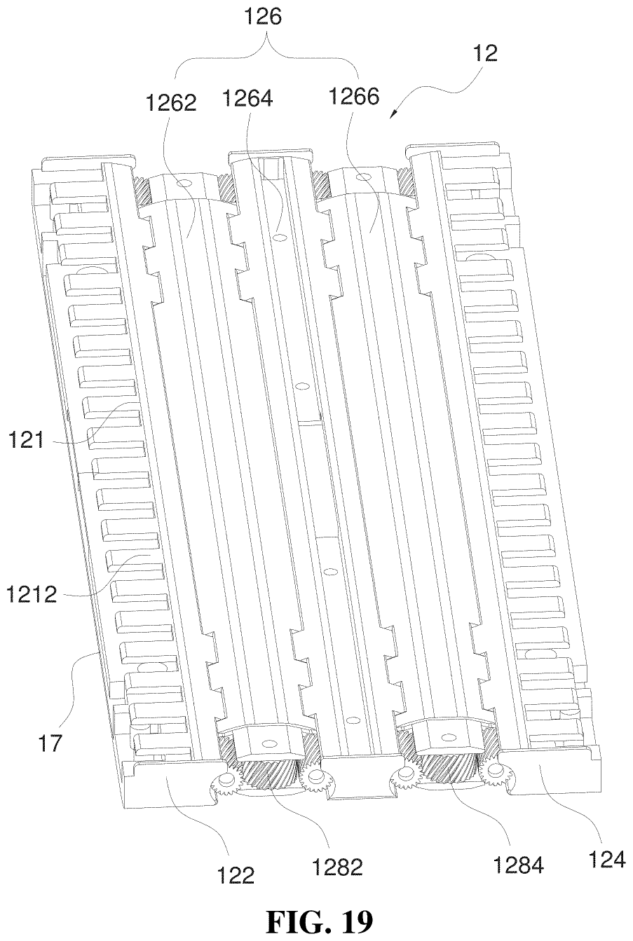

Referring to FIG. 18 and FIG. 19, in an embodiment of the present disclosure, when in the unfolded state the hinge module 12 has a plane shape which is in a substantially rectangular shape.

In this way, a shape of the hinge module 12 is regular, it is easy to form a regular-shaped bendable assembly 10, thereby facilitating supporting a regular-shaped flexible screen assembly and forming a regular-shaped flexible display device 100. Of course, the shape of the hinge module 12 is not limited to the shape in the embodiment discussed above, but can be set according to requirements in other embodiments.

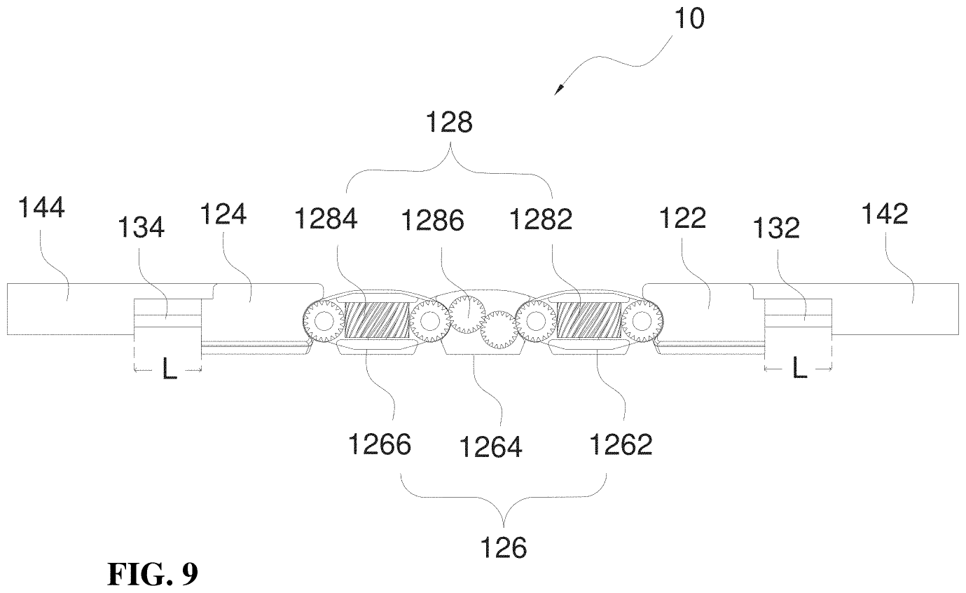

Referring to FIGS. 9 to 11, in some embodiments, the bending angle of the hinge module 12 varies in a range of 0-180 degrees. When the bending angle is 0 degree, the first connecting hinge 122, the second connecting hinge 124, and the rotatable shaft structure 126 are on the same plane. When the bending angle is larger than 0 degree, such as 90 degrees (as illustrated in FIG. 10) or 180 degrees (as illustrated in FIG. 11), the rotatable shaft structure 126 is bent, and the first connecting hinge 122 is substantially perpendicular to or in parallel with the second connecting hinge 124.

In addition, it is possible to install a reversal restricting structure(s) (not illustrated) at connections between the first connecting hinge 122 and the rotatable shaft structure 126 and between the second connecting hinge 124 and the rotatable shaft structure 126. In this way, reverse rotation (that is, reverse bending) of the hinge module 12 can be avoided. For example, it is possible to avoid that the bendable assembly 10 in a fully unfolded state or with the bending angle of 0 degree is further bent in an unfolding direction, thereby avoiding damage to the bendable assembly 10 and even the flexible display assembly 20 due to misoperation.

In some embodiments, the synchronous gear module 128 includes a third gear set 1286. The third gear set 1286 is disposed at one end of the second rotating shaft 1264 and rotatably connected with the first gear set 1282 and the second gear set 1284.

It can be understood that the third gear set 1286 is disposed between the first gear set 1282 and the second gear set 1284. The first gear set 1282 is spaced apart from the second gear set 1284. In this embodiment, there are two first gear sets 1282 arranged at two opposite ends of the hinge module 12, two second gear sets 1284 arranged at the two opposite ends of the hinge module 12, and two third gear sets 1286 arranged at the two opposite ends of the hinge module 12. A certain damping exists between a portion of the first gear set 1282 and a portion of the third gear set 1286 rotatably connected with the portion of the first gear set 1282, a certain damping exists between a portion of the second gear set 1284 and the other portion of the third gear set 1286 rotatably connected with the portion of the second gear set 1284, so as to ensure that the overall hinge module 12 is bent synchronously, that is, a rotation of any one gear of the hinge module 12 can drive the other gears of the hinge module 12 to rotate synchronously. At this point, the hinge module 12 is also bent to finally drive the bendable assembly 10 to be bent or unfolded.

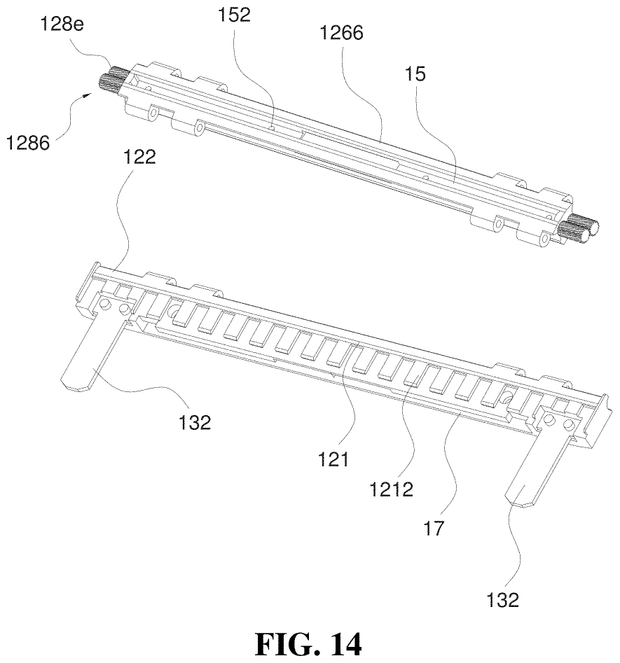

Referring to FIG. 14, in an embodiment, the third gear set 1286 includes two third gears 128e. The two third gears 128e perpendicularly rotates relative to the third rotating shaft 1264. One of the two third gears 128e is disposed below (or above) and meshes with the other. Similarly, the two third gears 128e each are in a substantially cylindrical shape. The two third gears 128e each are rotated in a rotation range of 0 to 360 degrees. It can be understood that the rotation range of each of the two third gears 128e refers to an angular range of its rotation around its central axis. That is, the two third gears 128e can revolve around themselves respectively. The third gears 128e may be all helical gears.

Further, in some embodiments, it is possible to adjust a degree of interference at a rotational junction of the first connecting hinge 122 and the rotatable shaft structure 126 and a degree of interference at a rotational junction of the second connecting hinge 124 and the rotatable shaft structure 126, that is, it is possible to adjust the damping at the rotational junction of the first gear set 1282 and the third gear set 1286 and the damping at the rotational junction of the second gear set 1284 and the other portion of the third gear set 1286, so as to adjust a rotational friction force generated at the rotational junctions. In this way, when the hinge module 12 is bent to have any bending angle, the rotating friction force is larger than the gravity of rotatable portions of the bendable assembly 10, and thus the bendable assembly 10 can be bent or unfolded to be fixed in current status under an external force.

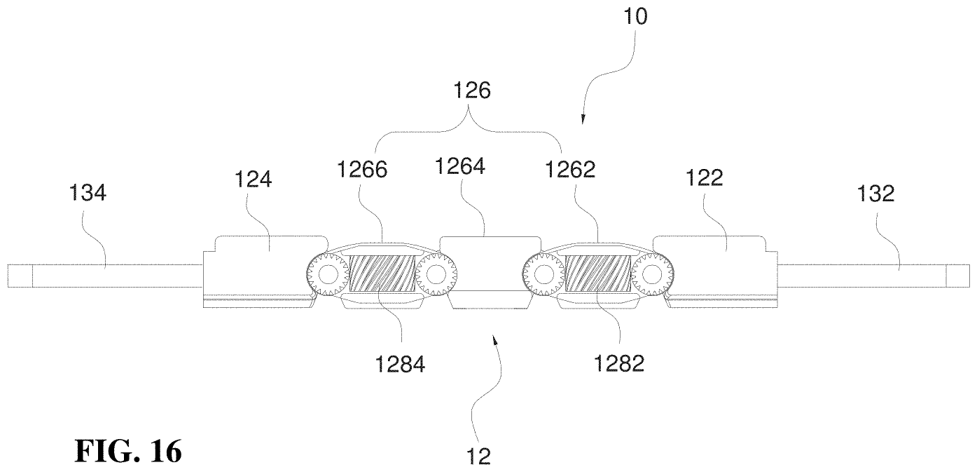

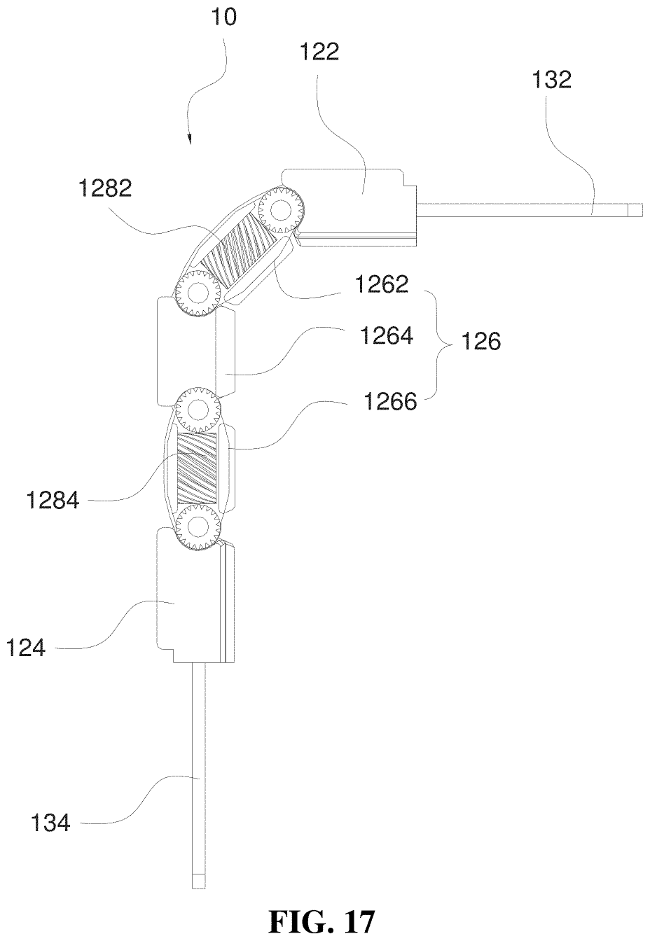

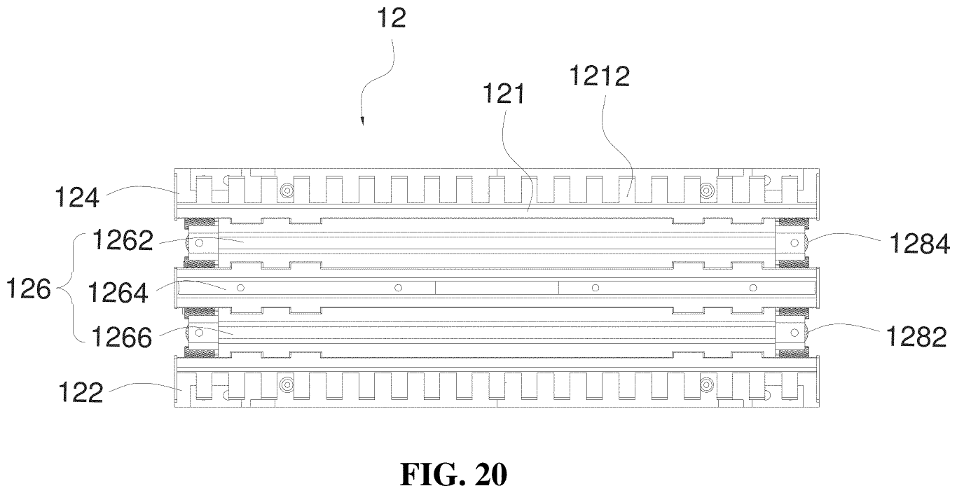

Referring to FIGS. 16 to 20, in some embodiments, the third gear set 1286 can be omitted from the synchronous gear module 128, and the other position and connection relationships remain unchanged, and the bentable assembly 10 can also be bent around the second rotating shaft 1264. The first connecting hinge 122 is bent synchronously with the second connecting hinge 124. The bending angle of the bendable assembly 10 can still be in a range of 0-180 degrees. By adjusting a damping between the first gear 128a and the second gear 128b, the bendable assembly 10 can be fixed at any angle within a range of the bending angle.

In an embodiment of the present disclosure, a deformation direction of the resilient member 16 is parallel to a slip direction of the connecting member 13. In this way, the stability of the bendable assembly 10 can be ensured when the hinge module 12 and the casing plate 14 moves relative to each other.

In an embodiment, when bending or unfolding the bendable assembly 10, the resilient member 16 deforms to generate a force that is applied against the hinge module 12 and the casing plate 14 to enable the hinge module 12 and the casing plate 14 to move relative to each other. At this point, a sliding of the connecting member 13 can guide the relative movement between the hinge module 12 and the casing 14a, such that the deformation direction of the resilient member 16 is parallel to the slip direction of the connecting member 13, and it can be understood to be that the resilient member 16 deforms in a same direction in which the connecting member 13 slidably moves.

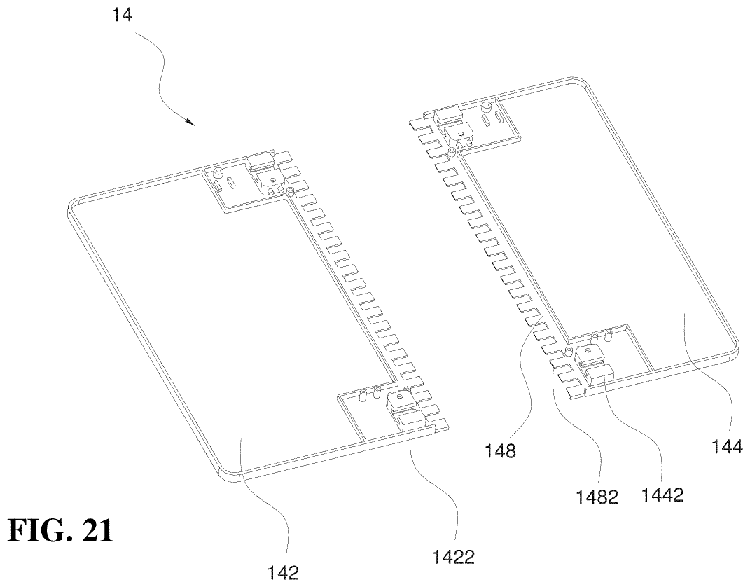

Referring to FIG. 14 and FIG. 21, in an embodiment of the present disclosure, the casing plate 14 includes a first side portion 148 facing the hinge module 12, and the hinge module 12 includes a second side portion 121 facing the casing plate 14. The first side portion 148 includes a first guiding structure 1482, and the second side portion 121 includes a second guiding structure 1212. The first guiding structure 1482 is fitted and connected with the second guiding structure 1212 to guide relative movement between the casing plate 14 and the hinge module 12.

In an embodiment, the first guiding structure 1482 and the second guiding structure 1212 are both in a comb-like structure and can be fitted with each other. Relative movement may occur between comb teeth, that is, the relative movement may occur between the casing plate 14 and the hinge module 12. The fitting and engagement of the comb teeth of the first guiding structure 1482 and the second guiding structure 1212 can provide a relatively good guiding, and thus the relative movement between the casing plate 14 and the hinge module 12 is relatively smooth, and it is not easy to cause offset.

In an embodiment of the present disclosure, one first guiding structure 1482 is formed at the first side portion 148 of the first plate 142 opposite to the first connecting hinge 122, and one first guiding structure 1482 is formed at the first side portion 148 of the second plate 124 opposite to the second connecting hinge 124. One second guiding structure 1212 is formed at the second side portion 121 of the first connecting hinge 122 opposite to the first plate 142, and one second guiding structure 1212 is formed at the second side portion 121 of the second connecting hinge 124 opposite to the second plate 144.

In one example, the casing plate 14 is made of metal or plastic. In this way, various material can be selected to manufacture the casing plate 14, which is beneficial to reduce the cost of the bendable assembly 10.

Referring to FIGS. 1 to 3, the flexible display device 100 is provided according to the embodiments of the present disclosure. The flexible display device 100 includes the bendable assembly 10 provided according to any of the above-mentioned embodiments and a flexible screen assembly 20 fixedly disposed on the bendable assembly 10.

By means of arranging the flexible screen assembly 20 on the bendable assembly 10 to form the flexible display device 100, the flexible screen 24 can be prevented from being damaged due to being bent and stretched, and thus relatively long service life and relative high product quality can be provided.

In an embodiment of the present disclosure, the flexible screen assembly 20 includes a flexible support plate 22 and a flexible screen 24. The flexible support plate 22 is fixedly connected with the bendable assembly 10. The flexible screen 24 is attached to a side of the flexible support plate 22 away from the bendable assembly 10.

By means of attaching the flexible support plate 22 to the flexible screen 24, the flexible support plate 22 can well protect the flexible screen 24, such that the flexible screen 24 is flat, aesthetic, and highly protective.

In some embodiments, the flexible support plate 22 is made of titanium alloy, stainless steel, carbon fiber composite material, or Kevlar.

The above materials have high strength, good rigidity, low density, light weight, high thermal strength, and good corrosion resistance, and are suitable as materials for the flexible support plate 22.

Referring to FIG. 3, in some embodiments, the flexible support plate 22 is fixed on the bendable assembly 10 via multiple fasteners 26 passed through the flexible support plate 22.

In an embodiment, the fasteners 26 are screws. The flexible support plate 22 provides with a protrusion 222. The protrusion 222 defines multiple first through holes 224. Referring to FIG. 14, the second rotating shaft 1264 defines a groove 15 corresponding to the protrusion 222. The groove 15 defines multiple second through holes 152. The protrusion 222 and the groove 15 can be positioned to fit with each other. The fasteners 26 pass through the first through holes 224 and the second through holes 152 to lock and fix the flexible support plate 22 to the hinge module 12. Further, in order to improve the stability, the flexible support plate 22 and the casing plate 14 can be fixed together by screw fixing, rivet fixing, double-sided tape bonding, or glue bonding. The screw fixing and glue bonding are simple to implement, mature in process, and low in price, and thus production cost and difficulty can be reduced and economic benefits can be improved.

In some embodiments, the flexible screen 24 includes an OLED screen.

The OLED screen also has self-luminous organic electro-excited light diodes, and thus has advantages of no need for a backlight, high contrast, thin thickness, wide viewing angle, and high response speed. The OLED screen can also be used for flexible panels and has a wide operating temperature range and simple structure and manufacturing processes.

In some embodiments, the flexible display device 100 includes a flexible rubber ring 30 wrapping an outer edge of the flexible support plate 22 and an outer edge of the flexible screen 24.

The flexible rubber ring 30 is formed of plastic through injection molding. The flexible rubber ring 30 has a relatively soft feel at room temperature, good thermal stability and electrical insulation, and thus can effectively protect an edge of the flexible screen 24 and an edge of the flexible support plate 22.

In the description of the specification, the description made with reference to terms such as “one embodiment”, “some embodiments”, “example”, “specific example”, or “some examples” means that a specific characteristic, structure, material or feature described with reference to the embodiment or example is included in at least one embodiment or example of the present disclosure. In this specification, exemplary descriptions of the foregoing terms do not necessarily refer to a same embodiment or example. In addition, the described specific features, structures, materials, or characteristics may be combined in a proper manner in any one or more of the embodiments or examples.

Although the embodiments of the present disclosure are illustrated and described above, it would be appreciated by those skilled in the art that, changes, modifications, alternatives, and variants can be made in the embodiments without departing from principles and purposes of the present disclosure, and the scope of present disclosure is defined by the claims and their equivalents.

What is claimed is:

1. A bendable assembly comprising:
a hinge module configured for being switched between a bent state and an unfolded state;
a casing plate; and
a resilient member connected with the casing plate and the hinge module;
the hinge module and the casing plate move toward each other during the bendable assembly switches from the unfolded state to the bent state, and the hinge module and the casing plate move relatively away from each other during the bendable assembly switches from the bent state to the unfolded state; and
the resilient member is configured to drive the casing plate and the hinge module to move relatively away from each other during the hinge module switches from the bent state to the unfolded state.

2. The bendable assembly of claim 1, wherein the resilient member is in a V-shape, the resilient member has one distal end connected to the casing plate and the other distal end connected to the hinge module.

3. The bendable assembly of claim 1, wherein the hinge module defines an accommodating groove, and the resilient member is partially received in the accommodating groove.

4. The bendable assembly of claim 1, wherein
the resilient member is linear shape;
the casing plate provides with a first positioning post;
the hinge module provides with a second positioning post; and
the resilient member is sleeved on the first positioning post and the second positioning post.

5. The bendable assembly of claim 1, wherein
the resilient member is linear shape;
the hinge module provides with a positioning rod;
the casing plate provides with a positioning seat, wherein the positioning rod has one end embedded in the positioning seat; and
the resilient member is sleeved on the positioning rod.

6. The bendable assembly of claim 1, wherein
the bendable assembly comprises a connecting member in a sheet shape, wherein the connecting member is slidably connected with the casing plate and the hinge module;
the connecting member guides the hinge module and the casing plate to move toward each other during the bendable assembly switches from the unfolded state to the bent state; and
the connecting member guides the hinge module and the casing plate to move relatively away from each other during the bendable assembly switches from the bent state to the unfolded state.

7. The bendable assembly of claim 6, wherein
the hinge module comprises a first connecting hinge, a second connecting hinge, and a rotatable shaft structure;
the casing plate comprises a first plate and a second plate;
the first connecting hinge and the second connecting hinge are respectively rotatably connected to two opposite sides of the rotatable shaft structure;
the connecting member comprises a first slide rail and a second slide rail;
the first slide rail is fixedly connected to the first connecting hinge and slidably connected to the first plate, or the first slide rail is fixedly connected to the first plate and slidably connected to the first connecting hinge; and
the second slide rail is fixedly connected to the second connecting hinge and slidably connected to the second plate, or the second slide rail is fixedly connected to the second plate and slidably connected to the second connecting hinge.

8. The bendable assembly of claim 7, wherein
under the condition that the first slide rail is slidably connected with the first plate, the first plate provides with a first sliding seat, and the first slide rail slidably passes through the first sliding seat; and
under the condition that the first slide rail is slidably connected with the first connecting hinge, the first connecting hinge provides with the first sliding seat, and the first slide rail slidably passes through the first sliding seat.

9. The bendable assembly of claim 7, wherein
under the condition that the second slide rail is slidably connected with the second plate, the second plate provides with a second sliding seat, and the second slide rail slidably passes through the second sliding seat; and
under the condition that the second slide rail is slidably connected with the second connecting hinge, the second connecting hinge provides with the second sliding seat, and the second slide rail slidably passes through the second sliding seat.

10. The bendable assembly of claim 7, wherein the first connecting hinge, the rotatable shaft structure, and the second connecting hinge rotate synchronously.

11. The bendable assembly of claim 10, wherein
the hinge module comprises a synchronous gear module;
the synchronous gear module comprises a first gear set and a second gear set; and
the first gear set is rotatably connected with the first connecting hinge and the rotatable shaft structure, and the second gear set is rotatably connected with the second connecting hinge and the rotatable shaft structure.

12. The bendable assembly of claim 11, wherein
the rotatable shaft structure comprises a first rotating shaft, a second rotating shaft, and a third rotating shaft, wherein the first rotating shaft and the third rotating shaft are respectively rotatably connected to two opposite sides of the second rotating shaft;
the first gear set is disposed at one end of the first rotating shaft; and
the second gear set is disposed at one end of the third rotating shaft.

13. The bendable assembly of claim 12, wherein the synchronous gear module comprises a third gear set, wherein the third gear set is disposed at one end of the second rotating shaft and rotatably connected with the first gear set and the second gear set.

14. The bendable assembly of claim 6, wherein a deformation direction of the resilient member is parallel to a slip direction of the connecting member.

15. The bendable assembly of claim 1, wherein the casing plate comprises a first side portion facing the hinge module, and the hinge module comprises a second side portion facing the casing plate, wherein the first side portion comprises a first guiding structure, and the second side portion comprises a second guiding structure, wherein the first guiding structure is fitted and connected with the second guiding structure to guide relative movement between the casing plate and the hinge module.

16. A flexible display device, comprising:
a bendable assembly comprising:
a hinge module configured for being switched between a bent state and an unfolded state;
a casing plate; and
a resilient member connected with the casing plate and the hinge module;
the hinge module and the casing plate move toward each other during the bendable assembly switches from the unfolded state to the bent state, and the hinge module and the casing plate move relatively away from each other during the bendable assembly switches from the bent state to the unfolded state; and
the resilient member is configured to drive the casing plate and the hinge module to move relatively away from each other during the hinge module switches from the bent state to the unfolded state; and
a flexible screen assembly fixedly disposed on the bendable assembly.

17. The flexible display device of claim 16, wherein the flexible screen assembly comprises:
a flexible support plate fixedly connected with the bendable assembly; and
a flexible screen attached to a side of the flexible support plate away from the bendable assembly.

18. The flexible display device of claim 17, wherein the flexible support plate is fixed on the bendable assembly via a plurality of fasteners passed through the flexible support plate.

19. The flexible display device of claim 17, wherein the flexible screen comprises an OLED screen.

20. The flexible display device of claim 17, wherein the flexible display device comprises a flexible rubber ring wrapping an outer edge of the flexible support plate and an outer edge of the flexible screen.
